(19) United States
(12) Patent Application Publication
(10) Pub. No.: US 2023/0266594 A1
(43) Pub. Date: Aug. 24, 2023

(54) DEVICES, SYSTEMS, AND METHODS FOR DIFFRACTION GRATINGS

(71) Applicant: SONY GROUP CORPORATION, Tokyo (JP)

(72) Inventors: Christophe PEROZ, Tokyo (JP); Yuichi TAKAI, Tokyo (JP)

(73) Assignee: SONY GROUP CORPORATION, Tokyo (JP)

(21) Appl. No.: 18/043,658

(22) PCT Filed: Sep. 8, 2021
(86) PCT No.: PCT/IB2021/000626

§ 371 Date: Mar. 1, 2023

Related U.S. Application Data
(60) Provisional application No. 63/075,416, filed on Sep. 8, 2020.
(60) Provisional application No. 63/080,649, filed on Sep. 18, 2020.
(60) Provisional application No. 63/086,711, filed on Oct. 2, 2020.

(51) Int. Cl. G02B 27/01; F21V 8/00; G03F 7/00

(52) U.S. Cl. CPC G02B 27/0172; G02B 6/0016; G02B 6/0036; G02B 6/0065; G03F 7/001; G03F 7/0002; G02B 2027/0178

(57) ABSTRACT

A waveguide comprises a substrate and a surface relief grating (SRG) comprising at least one waveguide material on the substrate. The at least one waveguide material includes a first pattern that alternates between first structures and first indentations. The first pattern has a substantially same first pitch over at least a first part of the substrate. A residual layer thickness (RLT) of the at least one waveguide material on the substrate over the first part of the substrate is less than a threshold value.

### FIELD

Diffraction gratings and systems and methods for producing diffraction gratings, including surface relief gratings, are provided.

### BACKGROUND

Diffraction gratings are optical components that have a structure for splitting and/or diffracting incident light. Surface relief gratings (SRGs) are one such type of diffraction grating useful in modern applications, such as for display devices implementing augmented reality (AG) and/or mixed reality (MR).

### SUMMARY

At least one example embodiment is directed to a waveguide comprising a substrate; and a surface relief grating (SRG) comprising at least one waveguide material on the substrate, the at least one waveguide material including a first pattern that alternates between first structures and first indentations, the first pattern having a substantially same first pitch over at least a first part of the substrate, where a residual layer thickness (RLT) of the at least one waveguide material on the substrate over the first part of the substrate is less than a threshold value.

At least one example embodiment is directed to a head mounted device (HMD) comprising a wearable frame; and a waveguide attached to the frame. The waveguide includes a substrate; and a surface relief grating (SRG) comprising at least one waveguide material on the substrate, the at least one waveguide material including a first pattern that alternates between first structures and first indentations, the first pattern having a substantially same first pitch over at least a first part of the substrate, where a change in residual layer thickness (RLT) of the at least one waveguide material on the substrate over the first part of the substrate is less than 50 nm/mm. The HMD further comprises an image generating device that generates light input to the waveguide.

At least one example embodiment is directed to a template for imprinting optical gratings, the template comprising a base; and a plurality of structures protruding from the base and arranged at a substantially same pitch over at least part of the base, where at least one of a duty cycle of the plurality of structures and a floor height of the plurality of structures is based on a desired residual layer thickness (RLT) of a material to be imprinted by the template.

### BRIEF DESCRIPTION OF THE FIGURES

FIG. 1 is a block diagram of a display device according to at least one example embodiment.

FIG. 2 illustrates a general diagram of an imprinting system according at least one example embodiment.

FIG. 3A illustrates a template according to at least one other example embodiment.

FIG. 3B illustrates another template according to at least one example embodiment.

FIG. 4 illustrates example floor height modulations of a template according to example embodiments.

FIG. 5A illustrates a schematic plan view and cross sectional views of a template according to at least one example embodiment.

FIG. 5B illustrates a waveguide with a waveguide area according to at least one example embodiment.

FIG. 6 illustrates various schematics of a wafer including one or more templates according to at least one example embodiment.

FIGS. 7A and 7B illustrate graphics for explaining diffraction efficiency of an SRG according to at least one example embodiment.

FIGS. 8A to 8D illustrate various views for forming an SRG with a variable refractive index according to example embodiments.

FIG. 9 illustrates a method for forming an SRG having a variable refractive index according to at least one example embodiment.

FIGS. 10A and 10B illustrate inkjet printhead systems according to at least one example embodiment.

FIGS. 11A to 11D illustrate plan views of various droplet patterns before and after droplet spreading according to at least one example embodiment.

FIGS. 12A to 12D illustrate methods for forming an SRG with structures having variable refractive indices in a vertical, or z-axis, direction according to at least one example embodiment.

FIG. 13 illustrates a schematic view of a head mounted display (HMD) according to at least one example embodiment.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It being understood that various changes may be made in the function and arrangement of elements without departing from the spirit and scope of the appended claims.

It will be appreciated from the following description, and for reasons of computational efficiency, that the components of the system can be arranged at any appropriate location within a distributed network of components without impacting the operation of the system.

Furthermore, it should be appreciated that the various links connecting the elements can be wired, traces, or wireless links, or any appropriate combination thereof, or any other appropriate known or later developed element(s) that is capable of supplying and/or communicating data to and from the connected elements. Transmission media used as links, for example, can be any appropriate carrier for electrical signals, including coaxial cables, copper wire and fiber optics, electrical traces on a PCB, or the like.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The terms “determine,” “calculate,” and “compute,” and variations thereof, as used herein, are used interchangeably and include any appropriate type of methodology, process, operation, or technique.

Various aspects of the present disclosure will be described herein with reference to drawings that may be schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “include,” “including,” “includes,” “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

The use of SRG-based waveguides as optical combiners is very attractive for the development of AR/MR displays. The efficiency and image uniformity of the SRG waveguide can be beneficially optimized by varying the height of the diffractive gratings along the optical path through the waveguide and by customizing the thickness variation of the waveguide. Inventive concepts propose a strategy for forming SRGs by nanoimprint lithography with a controlled and customized variation of the residual layer thickness underneath the imprinted SRGs in order to ensure high optical performance of an AR/MR display, for example, within a head mounted device (HMD).

The design of the diffractive SRGs governs the output image quality (e.g., brightness, resolution, uniformity, and/or the like) produced by the waveguide combiner. The use of gratings with variable heights or multi-heights is very beneficial for increasing the overall optical performance of the waveguide (e.g., eyebox efficiency and uniformity). The fabrication of such gratings by conventional lithography processes is complex and expensive because multiple steps of lithography and etching are used. One attractive solution is to replicate the SRGs in a cost-effective manner using nanoimprint lithography (NIL). In this case, the SRGs may first be defined in a master mold or template and duplicated on subsequent templates. The duplicated templates and the master template may then be used to replicate the SRGs onto a resist material deposited on the surfaces (one or both sides) of organic (e.g., polymer film/sheet) or inorganic (e.g., glass or crystal wafer/sheet) substrates.

In general, the NIL process leaves a residual layer underneath the imprinted structures. A thickness of the residual layer depends on the initial volume of dispensed resist and the feature sizes of the patterns or structures of the mold or template that imprints the resist. A thickness of the residual layer underneath the structures is referred to as the residual layer thickness (RLT) and may be determined by the conservation of the volume of the resist before and after imprinting. For resist dispensing methods like spin-coating or dip coating or others, the resist volume generally remains constant before and after imprinting, and as a consequence, the replication of SRGs may lead to a variation of the RLT through the gratings. This variation, referred to as ΔRLT, may have a negative and sometimes severe impact on the optical performance of the waveguides (e.g., image resolution, uniformity, and/or the like). Accordingly, at least one inventive concept relates to methods for forming SRGs by an NIL process where the RLT and/or ΔRLT is controlled as desired, for example, to be below a particular value or within a particular range. For example, inventive concepts propose to control RLT and/or ΔRLT within an NIL process for forming SRGs by taking into consideration correlations between the variation of resist volume and the height of the structures that makeup the SRGs in the design of the master mold or template in order to keep the absolute RLT value small and to customize (e.g., minimize or, alternatively, reduce) the variation of ΔRLT. In doing so, the total volume of the resist to be displaced ΔV_{dis} should remain constant (or vary as little as possible) and should be independent of the height of the structures that comprise the SRG. As discussed in more detail below, one or more of the above goals may be accomplished by adhering to certain conditions when forming the master mold or template, for example, by controlling a duty cycle of SRG structures on the template and/or by controlling a floor height of the SRG structures on the template.

At least one further inventive concept of the instant disclosure relates to dispensing a resist volume on-demand according to grating geometry by using an ink-jet process. In more detail, inventive concepts propose a strategy for fabricating printed diffractive gratings with variable efficiency by nanoimprinting resist material with variable refractive indices deposited by an ink-jet method. For example, one may vary the refractive index of a single structure within an SRG by tuning the refractive index of the structure itself. Thus, example embodiments relate to methods of forming SRGs with variable optical properties by direct imprinting of ink-jet resist with variable refractive indices. The height of structures within the SRG formed according to these methods may be kept constant or its variation is limited to a small range in order to minimize or reduce the ΔRLT underneath the gratings and avoid abrupt RLT changes.

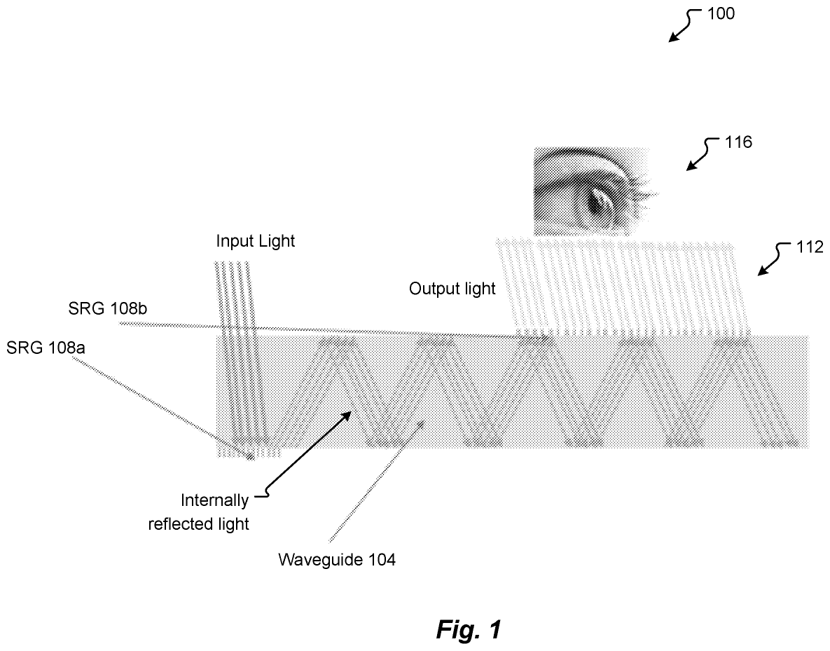

FIG. 1 is a block diagram of a display device 100 according to at least one example embodiment. The display device 100 includes a waveguide 104, one or more surface relief gratings 108, an eyebox 112, and a user 116.

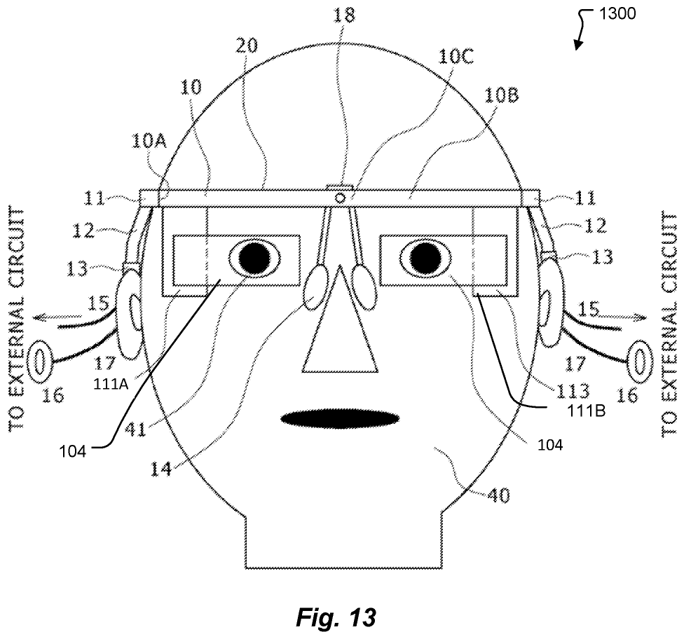

The waveguide 104 receives input light incident on a first surface of the waveguide 104 from a light source or an image generating device (not shown, but see FIG. 13 for additional detail of an image generating device), which is redirected (e.g., diffracted) by a first or input SRG 108a on a first surface of the waveguide 104 at an angle that causes internal reflection (e.g., total internal reflection (TIR)) within the waveguide 104. The internally reflected light may travel within the waveguide 104 before encountering a second or output SRG 108b at the first or a second surface of the waveguide 104. The waveguide 104 may be fixed to or on a substrate or base (not illustrated). The output SRG 108b has a structure that diffracts at least some of the internally reflected light to an eyebox 112 of the display device 100 as output light for viewing by a user 116. The input light may be generated by the light source under control of image processing circuitry (not shown) or an image generating device that controls the light source to output light in a manner that displays a still image and/or moving images to the user 116 through the eyebox 112, thereby providing an augmented reality image or mixed reality image to the user 116. The eyebox 112 may include an area or volume in which a user's eye will receive an acceptable view of the input light. The light source may comprise any suitable light source used for diffractive waveguide applications, for example, one or more light emitting diodes (LEDs) or other light source coupled with one or more lenses and/or prisms that direct light to the waveguide 104.

The above mentioned image processing circuitry or image generating device may comprise a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the image processing circuitry may comprise hardware, such as an application specific integrated circuit (ASIC). Other non-limiting examples of the image processing circuitry include an Integrated Circuit (IC) chip, a Central Processing Unit (CPU), a General Processing Unit (GPU), a microprocessor, a Field Programmable Gate Array (FPGA), a digital signal processor (DSP), a collection of logic gates or transistors, resistors, capacitors, inductors, diodes, or the like. Some or all of the image processing circuitry may be provided on a Printed Circuit Board (PCB) or collection of PCBs. It should be appreciated that any appropriate type of electrical component or collection of electrical components may be suitable for inclusion in the image processing circuitry.

The waveguide 104 may comprise any suitable material for diffractive waveguide applications, for example, glass, plastic, polymer, or other suitable organic or inorganic optical material. The waveguide 104 may be implemented in any suitable manner. For example, the waveguide 104 may comprise a core and one or more cladding layers, where the core and the cladding layer(s) have different dielectric constants. In another example, the waveguide 104 may be implemented with silicon photonics.

The SRGs 108a and 108b may comprise structures (e.g., protrusions and/or indentations) at first and/or second surfaces of the waveguide 104. The structures of each SRG 108a and 108b may be formed according to the NIL methods and/or ink-jet methods described below. The structures of each SRG 108a and 108b may be formed on the surface(s) of the waveguide 104 (i.e., the structures are not part of the waveguide 104, but instead placed on the surface(s) of waveguide 104) and/or included as part of the surface(s) of the waveguide 104. As described in more detail below, the structures of each SRG 108a and 108b may take any suitable shape or form. For example, the structures may comprise one-dimensional structures (e.g., linear structures), two-dimensional structure (pillars, holes, and/or the like), metasurfaces, and/or other suitable form. In any event, the specific design of the structures in an SRG 108 may be based on the optical characteristics desired for the output light of the display device 100.

The eyebox 112 may correspond to a volume of free space where the eye of a user 116 receives an acceptable view of an image created by the light from the output SRG 108b with respect to a set of criteria and thresholds. The size and location of this volume may be based on by optical architecture choices in which designers trade-off a number of constraints, such as field of view, image quality, and product design.

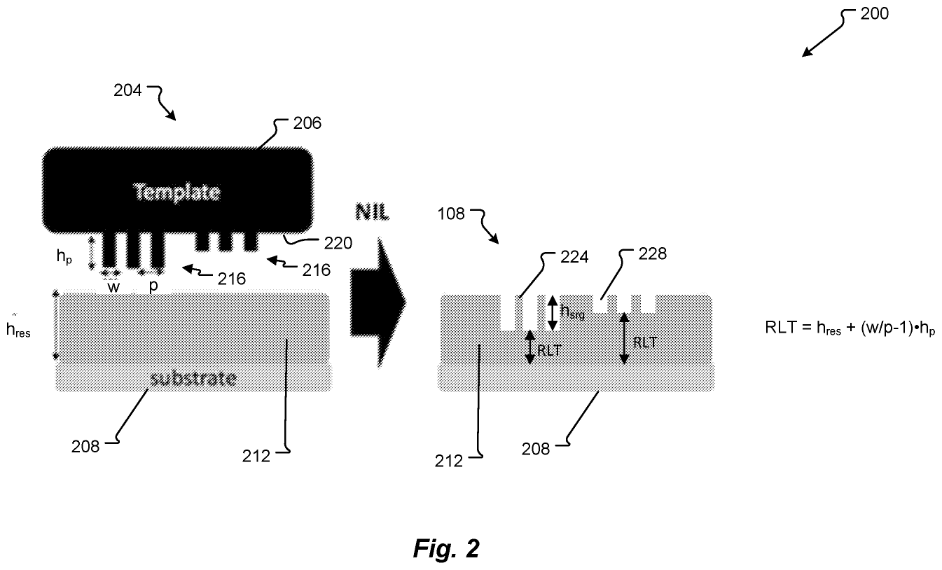

FIG. 2 illustrates a general diagram of an NIL system 200 according at least one example embodiment. The system 200 includes a template 204, a substrate 208, and resist 212 on the substrate 208. As shown, the template 204 includes a pattern of structures 216 that protrude from a main surface 220 of a base 206 of the template 204. The structures 216 are illustrated as being linearly shaped in the side or cross-sectional view of the template 204, but example embodiments are not limited thereto, and the shape, size, and form of the structures 216 may vary depending on the desired design for the SRG 108. The structures 216 may extend some distance into and/or out of the page so that upon imprinting the resist 212, trenches or indentations are formed in the resist 212. The left side of the figure illustrates the resist 212 prior to imprinting by the template 204 while the figure on the right illustrates the resist 212 after the template 204 has been applied to the resist 212. As shown, the resist 212 has an initial height hᵣₑₛ while the structures 216 have respective heights hₚ and respective widths w (height and width only shown for one set of structures 216). In addition, the structures 216 have a pitch p, which corresponds to a distance between an edge on a first side of one structure 216 and an edge on the first side of an immediately adjacent structure 216. Said another way, the pitch p corresponds to a period of the pattern created by the structures 216. As shown, the structures 216 of the SRGs 108 may correspond to holes or indentations 228 in the resist 212 that create pillar-like structures 224 in a cross sectional view. The depth of an indentation 228 or height of a structure 224 corresponds to h_{srg} which may be substantially equal to the height hₚ of a structure 216. In addition, a width of an indentation 228 may be substantially equal to the width w of a structure 216 while a pitch between structures 224 may also be substantially equal to pitch p between structures 216. Meanwhile, a width of a structure 224 may be substantially equal to a difference between the pitch p and the width w. The structures 224 and indentations 228 may span the entire or partial width of the resist 212 (which may also correspond to an entire or partial width of a waveguide 104).

The substrate 208 may comprise any suitable substrate for supporting the formation of the SRGs 108 using the template 204. Thus, the substrate 208 should have properties that can withstand an NIL process. In at least one example embodiment, the substrate 208 comprises a waveguide material, such as glass, plastic, polymer, or other suitable organic or inorganic optical material, which enables the substrate 208 to be part of the final waveguide 104 with one or more SRGs 108. In this scenario, the substrate 208 may include a waveguide material having a refractive index that matches or that is near a refractive index of the resist 212. Thus, the resist 212 may also comprise a waveguide material such as glass, plastic, polymer, or other suitable organic or inorganic optical material. In the event of a mismatch between refractive indices of the resist 212 and the substrate 208, the dimensions of the SRGs 108 (e.g., the dimensions of structures 224 and indentations 228) may be adjusted to reduce the effect of the mismatch on light passing through the interface between the substrate 208 and the resist material 212 of the SRG 108.

As also shown in FIG. 2, the residual layer thickness RLT of the resist 212 after imprinting by the template 204 corresponds to a distance between a top surface of the substrate 208 and a bottom end surface of an indentation 228 within the SRG 108. In general, for a particular pattern of structures 216 of the template 204 having widths w and a pitch p, RLT=hᵣₑₛ+((w/p)−1)·hₚ. In at least one embodiment, the pitch p is between about 150 nm and about 400 nm, the widths w are between about 100 nm and about 300 nm, and the heights hₚ are between about 5 nm to about 150 nm. In an embodiment where the structures 216 include metasurfaces or metamaterial structures, then the pitch p may be from about 20 nm to about 150 nm with the widths w and heights hₚ being in the same ranges noted above. In general, abrupt changes in RLT of the resist 212 over an SRG 108 and/or large variations in RLT over an SRG (e.g., due to substrate unevenness and/or imprinting errors) have negative impacts on optical key performance indicators (KPIs) for the display device 100. Such KPIs may include brightness, resolution, uniformity, and/or the like. Accordingly, at least one example embodiment relates to controlling RLT of an SRG 108 in a manner that improves one or more KPIs of the display device 100. In at least one embodiment, inventive concepts propose a strategy for designing an NIL master template 204 that enables customization and minimization (or reduction) of RLT and/or the variation of RLT when, for example, imprinting SRGs 108 with variable grating or structure 224 heights, therefore resulting in improved optical performance of the system.

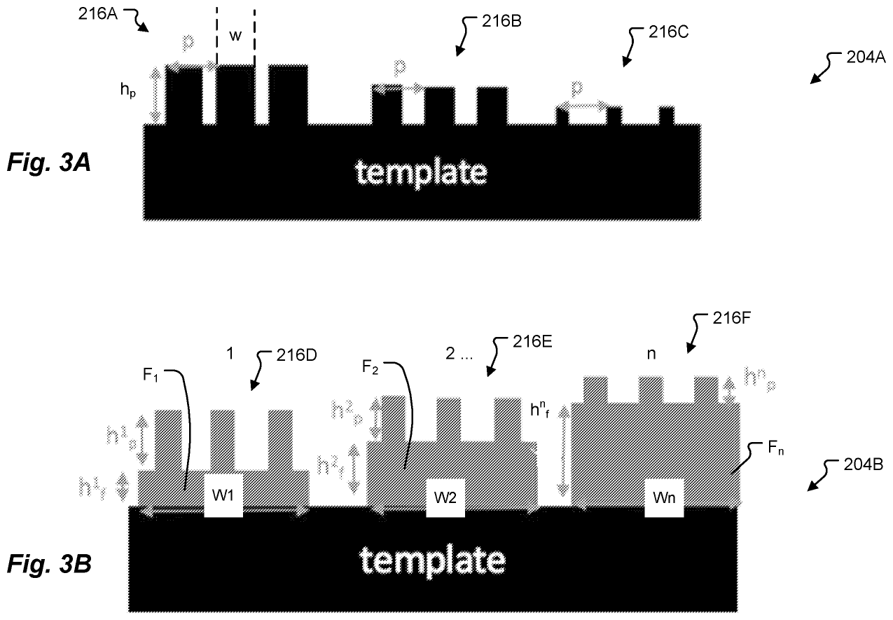

In general, at least one example embodiment takes into consideration the variation of volume of the resist 212 in relation to the height hₚ of the structures 216 (or height h_{srg} of structures 224) in the design of a template 204 in order to keep the absolute RLT value small (e.g., as small as possible) and/or to customize/minimize ΔRLT over a given length of the SRG 108 or waveguide 104. Here, it should be appreciated that the total volume of the resist 212 to be displaced by the structures 216, referred to as ΔV_{dis}, should be kept constant (or vary as little as possible) irrespective of the height hₚ of the structures 216 (or height h_{srg} of structures 224). The solutions presented below may be implemented to keep ΔRLT<50 nm/mm. In another example, ΔRLT<10 nm/mm. As discussed in more detail below with reference to FIGS. 3A and 3B, two strategies may be used separately or in conjunction with one another.

FIG. 3A illustrates a template 204A according to at least one example embodiment. In an NIL process, the template 204A is imprinted into resist 212 on a substrate 208 to form an SRG 108 with structures 224. In general, the efficiency of an SRG 108 is affected by pitch, height, and refractive index of the structures 224 in the SRG. However, the efficiency of an SRG 108 is less sensitive to a duty cycle of the structures that form the SRG 108. Accordingly, the template 204A shows an example where the duty cycles of the structures 216A, 216B, and 216C are tuned according to a desired height of the structures 224 in an SRG 108, where the height h_{srg} of the structures 224 in the SRG 108 corresponds to the height hₚ of the structures 216A, 216B, and/or 216C. In at least one example embodiment, the duty cycle of each set of structures 216A, 216B, and 216C is based on a height of at least one structure 216 in a respective set of structures 216A, 216B, and 216C. As shown in FIG. 3A, the structures in each set of structures 216A to 216C have a substantially same height hₚ (height hₚ only labeled for structures 216A). The duty cycle of the structures in each set of structures 216A to 216C may be defined by a ratio between a width w of each structure the pitch p between adjacent structures (e.g., for a group of structures 216A with a substantially same height hₚ, duty cycle=w/p). As shown, the duty cycle for structures 216B is smaller than the duty cycle for structures 216A and greater than the duty cycle for structures 216C while the pitch p remains constant across the structures 216A to 216C. In other words, the ratio w/p becomes larger as the height of the structures 216A, 216B, or 216C becomes larger. In at least one example embodiment, the ratio of w/p in each set of structures 216 that have substantially the same height should be maintained between 1/5 and 4/5 which may result in improved efficiency of the resulting SRG 108 after imprint.

In at least one embodiment, the structures 216 of a template 204 adhere to the following equation: Δ|(DT−1)·hₚ|=Δ|RLT|, where DT=w/p and hₚ is the height of a structure 216. Adhering to this equation for the template 204A may keep RLT of the eventually formed SRG 108 at a fixed value.

As may be appreciated from FIG. 3A, the duty cycle of a set of structures 216 varies proportionally to the height hₚ, which corresponds to the height of structures in the SRG 108. In one embodiment, the RLT value is less 50 nm. In at least one other embodiment, RLT may be defined as follows: 3-5 nm<RLT<=20 nm because a thinner RLT is beneficial for optical performance while maintaining enough thickness for sufficient adhesion of resist 212 to the substrate 208. As may be appreciated, the duty cycle for one given SRG height (which corresponds to height hₚ) may be calculated according to the equation noted above to keep RLT substantially constant. One benefit of this approach is that the manufacturing of template 204A may be accomplished with a lithography technique that achieves high pitch accuracy (<10 pm), which enables well defined properties of the SRGs 108. As noted above, the duty cycle may be kept between 20% and 80% (or even 10% to 90%) for easier manufacturing.

Here, it should be appreciated that the above-described pitch, height, width, and duty cycle of structures 216 of the template 204A also govern the pitch, height, width, and duty cycle of structures 224 of the finally formed SRG 108. Accordingly, the above described equation for controlling RLT may be solved using parameters for structures 224 of an SRG 108 that correspond to the above-described parameters of the template 204A.

FIG. 3B illustrates an example template 204B according to at least one other example embodiment. FIG. 3B relates to an example for tuning the floor height h_{f} of floors F of the structures 216D, 216E, and 216F for a fixed pitch p and a fixed duty cycle (w/p). The floor heights hⁿ_{f} of the floors F of structures 216D to 216F (which corresponds to the waveguide material remaining underneath the SRGs 108) can be tuned to keep ΔV_{dis} substantially constant and to minimize or reduce ΔRLT for a pattern of structures 224 with different heights h_{srg}.

The idea is to compensate the variation of displaced resist volume ΔV_{dis} by varying the floor heights of the structures 224 in an SRG 108 according to the heights h_{srg} of the structures 224. Thus, the floor height in the template 204B is varied inversely proportional to the height of SRGs structures as defined by the equation below for two neighboring floors, n and m of the template 204B with each floor n and m having a same total area but with structures 216 of different heights: (hⁿ_{f}·pⁿ)−(h^{m}_{f}·p^{m})=(DT^{m}−1)h^{m}ₚ−(DTⁿ−1)hⁿₚ, where p is the pitch of the structures 216 (which are substantially the same for each floor n and m) and where DT=w/p for a respective floor n or m (w and p defined for each floor n and m in the same manner as in FIG. 3A).

From a practical point of view, the maximum variation ΔV_{dis} between different structure heights of an SRG 108 may be such that ΔRLT<10 nm-20 nm. In other examples, ΔRLT<100 nm, ΔRLT<50 nm, ΔRLT<20 nm, or ΔRLT<5 nm.

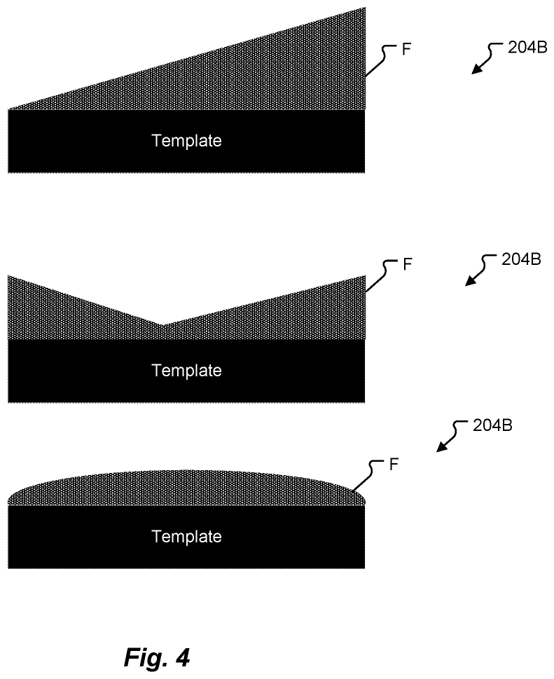

As may be appreciated, the floor height pattern of a floor Fi to Fₙ may be tuned with various geometries for optimizing or improving the optical performance of the waveguide 104. In one non-limiting example, a template 204B employs a gradual variation of the floor heights in order to avoid abrupt variation of the RLT. FIG. 4 illustrates schematic representations for a non-exhaustive set of examples of floor height modulation for floors F of a template 204B according to at least one example embodiment. FIG. 4 illustrates three possible floor height modulations of a wedge pattern, double wedge pattern with upward and downward slopes, and a dome pattern. However, example embodiments are not limited thereto, and the floor height of a floor F may be modulated in other manners to meet various optical performance requirements for a waveguide. The modulations illustrated in FIG. 4 and other, unillustrated, modulations may be determined based on geometries defined by Zernike coefficients.

Structures 216 are not shown in FIG. 4 but should be generally understood to protrude from the floors F of the example templates 204B, where the structures 216 at a particular location have heights that are inversely proportional to the floor height at that location (see, for example, FIG. 3B). In addition, it should be appreciated that FIG. 4 illustrates schematic representations of varied floor heights for floors F to show how the floor heights may vary generally. In real-world applications, such floors F may have less precise appearing shapes and/or gradations than those illustrated in FIG. 4.

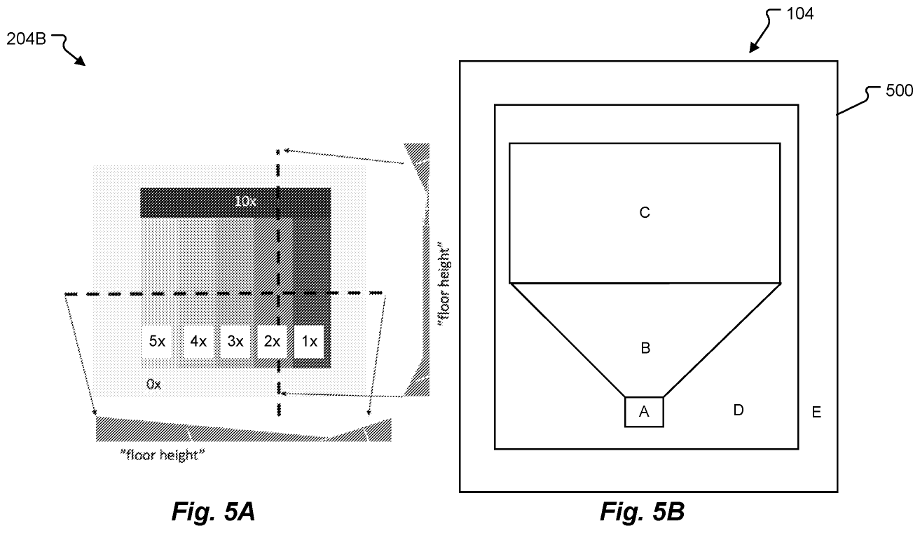

In at least one example embodiment, the floor height pattern of a floor F may be designed to smooth the RLT variation through different areas on a waveguide 104 for structures 216 of a fixed height. FIG. 5A illustrates a schematic plan view and cross sectional views of a template 204B that accommodates structures 216 (not shown) with a fixed height ‘x.’ As denoted by 0×, 1×, 2×, 3×, 4×, 5×, and 10× and the cross sectional views in FIG. 5A, the template 204B may have a varying floor height pattern that is a multiple of x (e.g., from 0× to 10×), where x is a fixed height of one of the structures 216. Having a floor height pattern according to FIG. 5A may avoid abrupt transitions in the final SRG 108, and thus, improve optical performance the waveguide 104 having the SRG 108.

FIG. 5B illustrates a waveguide 104 with a waveguide area 500 according to at least one example embodiment. Compared to FIG. 5A, which relates to varying floor heights of the entire waveguide 104 (not just sections that correspond to SRGs 108). Accordingly, the waveguide 104 of FIG. 5B may be formed by a template 204 that includes sections with structures 216 and sections without structures 216. The waveguide area 500 includes zones A to E and each zone may correspond to a different section of a waveguide 104. For example, zone A may correspond to an input coupling region of a waveguide 104 that receives input light. Zone B may correspond to a light propagation or light spreading region of the waveguide 104 where light received from zone A spreads and propagates toward the pupil expansion and output coupling region of zone C. Zone D may correspond a light management region and may include a nonpatterned region of the waveguide area 500 that surrounds zones A to C, as shown. Zone E may surround zone D and may correspond to a light absorption region that absorbs light. One or more of the zones A to E may include SRGs 108 formed by structures 216 of a template 204. For example, the output coupling region of zone C may correspond to a region in which structures 216 exist for the purpose of creating an SRG 108 in a waveguide 104 so that light is diffracted by the SRG 108 to an eyebox 112. Here, it should be appreciated that the waveguide area 500 may include more or fewer zones than discussed above depending on the specific design of the waveguide 104. In addition, an SRG 108 formed in or on one of the zones A to E may be at any surface of the waveguide 104 (e.g., an SRG 108 can be formed at the top and/or bottom surface of a waveguide 104 as indicated in FIG. 1, for example).

With reference to FIG. 5B, the same or similar strategy described above with reference to FIG. 5A may be applied to an entire waveguide area 500 to create a customized total thickness variation (TTV) over the whole waveguide 104 that helps control the optical properties of the waveguide 104. As waveguides may be sensitive to TTV, this approach is useful for achieving local thickness variation (LTV) in a simple and cost-effective manner during the forming of the templates themselves, which avoids expensive polishing steps or other less efficient methods for controlling the TTV of the waveguide material after formation of the waveguide. Said another way, the concept of adjusting the floor height patterns illustrated in FIG. 4 for sections of template 204 that include structures 216 for forming SRGs 108 may be carried through to the entire waveguide area 500 to control TTV of a waveguide 104 itself during manufacturing. Controlling the TTV of the entire waveguide 104 is particularly attractive when implemented in conjunction with floor height variations for the structures 216 of template 204B. In this case, one can locally predefine desired TTV patterns of multiple waveguides (e.g., using multiple templates on a wafer formed from a master template) so that each waveguide has a TTV pattern that ensures reproducibility of the optical performances of the waveguide.

In at least one example embodiment, each zone A to D of the waveguide area 500 has an associated floor height modulation. For example, zone A may be flat (e.g., no modulation or a constant floor height), zone B may have a wedge function (see FIG. 4), zone C may have a shape for a focus function as defined by Zernike term 4Z (2,0) and 12 (4,0), and zone D may have a shape for a tilt function as defined by Zernike term 1Z (1, −1) and 2(1,1). Optionally, zone E may have a shape for another desired function as defined by one of the Zernike terms. However, example embodiments are not limited to these floor height modulations and the floor height modulations of each zone may be varied according to the design of a waveguide 104.

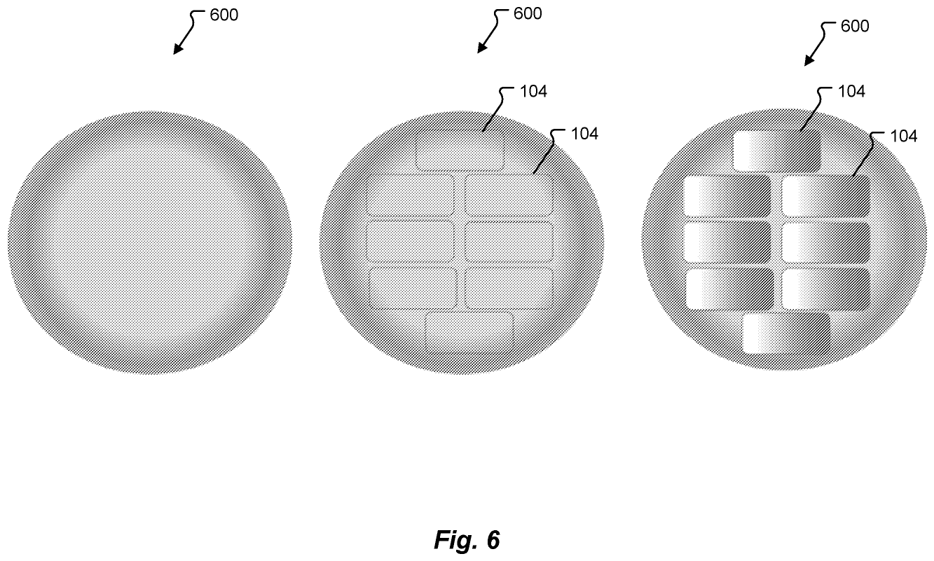

FIG. 6 illustrates various schematics of a wafer 600 including one or more templates 204 according to at least one example embodiment. In more detail, FIG. 6 illustrates three schematic views: a plan view of a wafer 600 (left graphic), a plan view of the wafer 600 having imprinted waveguides 104 without TTV variation (middle graphic), and a plan view of the wafer 600 having waveguides 104 with TTV variation. In general, thickness variation in FIG. 6 is indicated with greyscale gradations, where lighter shades correspond to thicker parts of material. As may be appreciated, the wafer 600 may already include thickness variation achieved with polishing techniques. In one example, the TTV of the wafer 600 may controlled to be less than 500 nm, or in some cases, less than 200 nm, over the entire wafer 600. However, example embodiments are not limited thereto, and other TTV values of the wafer 600 may be used. In both the middle and right graphics, it should be appreciated that the waveguides 104 may be formed on the wafer 600 according to the methods described herein (e.g., by imprinting waveguide resist on the wafer 600 with a template 204 in an NIL process).

In at least one example embodiment and with reference to the right graphic in FIG. 6, each waveguide 104 to which TTV has been applied may have a TTV value determined by the height profile in the mold. For example, a TTV value of each waveguide 104 may be between about 400 nm to about 1000 nm, which may enable a greater number of waveguides 104 to be produced on one wafer 600. As may be appreciated, FIG. 6 illustrates eight waveguides 104 on a wafer 600, however, more or fewer waveguides 104 may be included on a wafer 600 depending on wafer size and waveguide size. In addition, it should be appreciated that FIG. 6 is a schematic representation of waveguides 104 on a wafer 600 and that, in practice, the waveguides 104 may have other suitable sizes, shapes, and floor heights.

Example embodiments will now be described with reference to methods of fabricating diffractive gratings with variable efficiency for a waveguide-based display used, for example, in AR/MR applications.

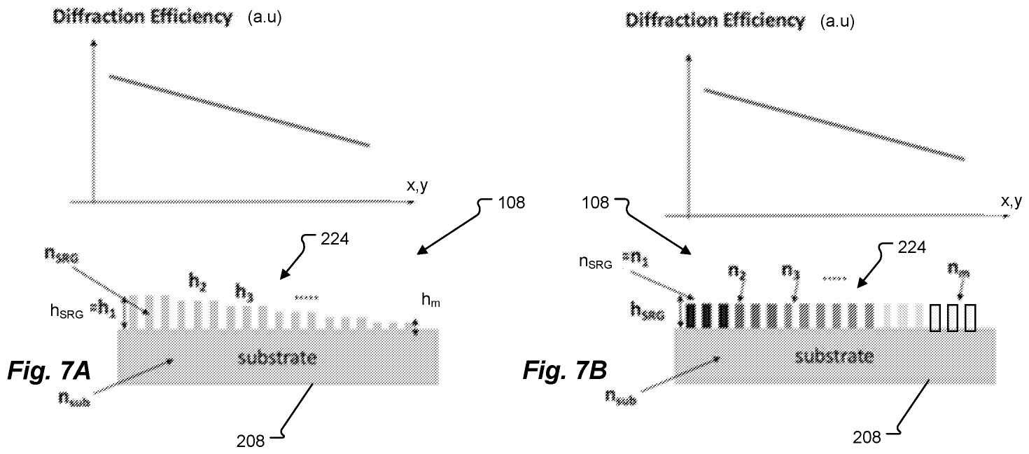

FIGS. 7A and 7B illustrate graphics for explaining diffraction efficiency of an SRG 108 according to at least one example embodiment. As shown in FIG. 7A, for example, diffraction efficiency is reduced as a height h_{SRG} of SRG structures 224 on a substrate 208 becomes lower from h₁ to hₘ. In FIG. 7A, the duty cycle and refractive index of the structures 224 are substantially constant for all structures 224. Meanwhile, as shown in FIG. 7B, diffraction efficiency of an SRG 108 is reduced as a refractive index n_{SRG} of the structures 224 becomes lower from n₁ to nₘ. In FIG. 7B, the duty cycle and the height of the structures 224 are substantially constant for all structures 224. At least one example embodiment relates to controlling diffraction efficiency of an SRG 108 using structures 224 with variable refractive indices. For example, with reference to FIG. 5B, the spatial tuning of the diffraction efficiency of an SRG 108 may be useful for zone C and may also be applied in zones B and D.

At least one example embodiment relates to fabricating imprinted diffractive gratings or metasurfaces with controlled efficiency by imprinting resist with spatial variation of their refractive index according to the desired efficiency of the SRG 108. Methods according to example embodiments may be suitable for manufacturing waveguides for use in AR (or MR) displays, which use diffractive gratings with relatively small diffraction efficiencies, typically varying between 0.01% and 10%, or between 0.05% and 5%. Tuning the refractive index of the gratings themselves enables an additional degree of freedom to control the diffraction efficiency and limit the overall height variation of the pattern, and subsequently limit the variation of RLT. As an example, in order to tune the diffraction efficiency (1^{st} order) from 0.05% to 5% of a 520 nm pitch grating with a 50% duty cycle using a single resist material with a refractive index of n=1.55, the depth or height of the gratings (e.g., structures 224) should be between 10 and 228 nm (Δh=100 nm). However, tuning the refractive index of the resist between n=1.55 and n=2.0 (Δn=0.45), Δh may be reduced by a factor two (from 10 nm to 60 nm), therefore simplifying the fabrication of master mold for NIL replication and reducing the overall variation of RLT in the final waveguide 104.

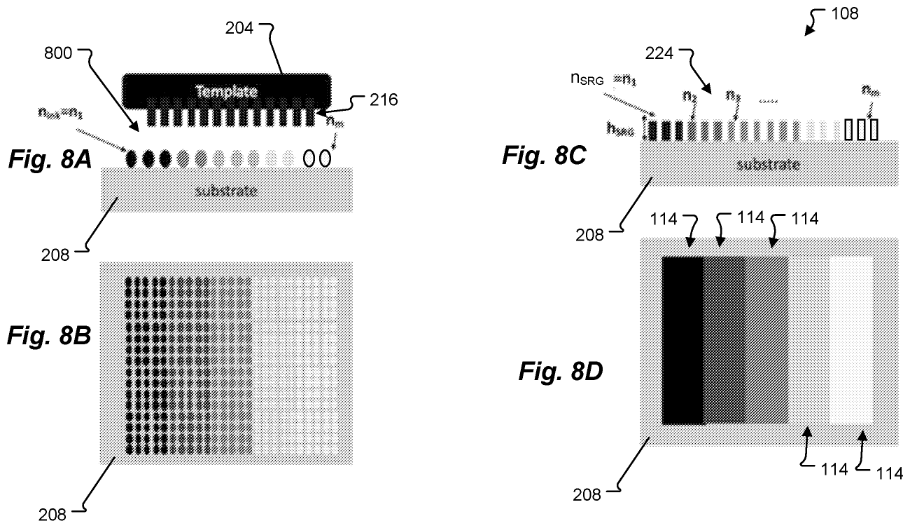

FIGS. 8A to 8D illustrate various views for forming an SRG 108 with a variable refractive index according to at least one example embodiment. In more detail, FIG. 8A illustrates a cross-sectional view of a substrate 208 including a plurality of droplets 800. As shown in the plan view of FIG. 8B, the droplets 800 may be arranged in a matrix of rows and columns. The droplets 800 are illustrated with different greyscale values to indicate changes in refractive index from n₁ to nₘ. As shown, the droplets 800 may include multiple subsets of droplet columns that have different refractive indexes n₁ to nₘ. As discussed in more detail below, the droplets 800 may be deposited via inkjet printing.

Thus, as in FIG. 8A, each droplet 800 corresponds to a droplet of ink having one of the refractive indices n₁ to nₘ. The number of droplets in column of droplets the number of columns containing droplets of a particular refractive index may vary according to design preferences. In at least one example embodiment, a same number of columns of droplets exists for different refractive index. In other words, if forming an SRG 108 with 15 columns of ink droplets having five different refractive indices, then the droplets 800 may be dispensed such that there are 3 columns of droplets 800 for each of the five different refractive indices used.

FIG. 8A shows applying a template 204 after the droplets 800 are deposited to form the SRG 108 in the cross-sectional view of FIG. 8C. In this example, the structures 216 of the template 204 have substantially same heights and a constant duty cycle so that the structures 224 of the SRG 108 in FIG. 8C have substantially same heights and a constant duty cycle. FIG. 8D illustrates a plan view schematic representation of how sections of equal widths are formed that contain the structures 224. That is, in at least one example embodiment, each subset of structures 224 with a respective refractive index may occupy the substantially same amount of space on the substrate 208 as the other subsets of structures 224 having their respective refractive indices. However, example embodiments are not limited thereto, and the specific design may be varied accordingly.

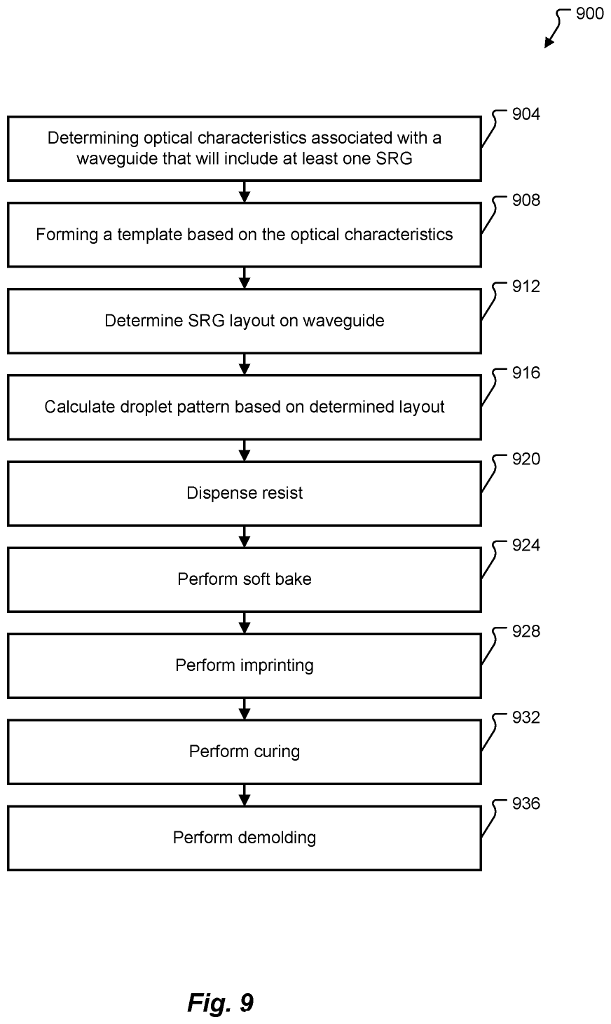

FIG. 9 illustrates a method 900 for forming an SRG 108 having a variable refractive index according to at least one example embodiment. In general, the proposed process includes dispensing resist droplets with desired refractive indices in a controlled manner with ink-jet techniques, nanoimprinting the resist with a template, and performing curing. At least one example embodiment employs a single solvent-free resist material with a refractive index between about 1.50 and about 1.80 and low resist viscosity, typically below about 30 mPa·s. In addition, the imprinted patterns may be transferred by plasma etching into an underlayer or film on the substrate 208 or into the substrate 208 itself.

Operation 904 includes determining optical characteristics associated with a waveguide 104 that will include at least one SRG 108. The determined optical characteristics may include characteristics associated with the at least one SRG 108, such as a desired diffraction efficiency along the at least one SRG 108, eyebox efficiency, image uniformity, image brightness, image resolution, and/or the like. In at least one embodiment, the optical characteristics include characteristics of parts of the waveguide 104 that do not include an SRG 108, such as internal reflection characteristics of the waveguide 104, waveguide material, and/or the like. The optical characteristics may be determined by a user or manufacturer of the waveguide 104 with or without the assistance of processing circuitry. For example, a user may provide input to the processing circuitry indicating a desired image resolution within the eyebox 112 of the display device 100 and/or other desired image characteristics of an output image. The processing circuitry may use the user-provided image resolution and/or other image characteristics to determine the appropriate diffraction efficiency, RLT, and/or ΔRLT for the at least one SRG 108 and/or the rest of the waveguide 104 that achieves the desired image characteristics. For example, the processing circuitry may access a lookup table (LUT) store in memory coupled to the processing circuitry that contains information that associates traits of an SRG 108 and/or waveguide 104 to image characteristics achieved with those traits of the SRG 108 and/or waveguide 104. Here, it should be appreciated that the processing circuitry may have the same or similar structure as the image processing circuitry described in the discussion of FIG. 1.

Operation 908 includes forming a template 204 according to the optical characteristics determined in operation 904. For example, the processing circuitry, with or without user input, may control an etching apparatus (e.g., for dry etching, wet etching, and/or laser etching) or other device suitable to create the template 204 with structures 216. The structures 216 of template 204 may be formed according to one or more of the equations described herein for adjusting duty cycles and/or floor heights so that a desired RLT and/or a desired ΔRLT is achieved in the finally formed SRG 108. The template 204 may be formed of a material, such as silicon, metal, or other suitable material used for templates in NIL processes.

Operation 912 includes determining a layout for an SRG 108 on a waveguide 104. The layout may be determined by the processing circuitry based on one or more desired properties for the SRG 108 and/or the waveguide 104. For example, the layout of the SRG 108 may be determined according to the same or similar optical characteristics from operation 904, such as a desired diffraction efficiency along the SRG 108, which in turn, may determine image quality of an AR or MR display. Determining the layout of an SRG 108 may include determining how a resist of waveguide material should be dispensed on the substrate 208 so that the application of the template 204 results in a waveguide 104 with an SRG 108 that meets or nearly meets the optical characteristics from operation 904. As may be appreciated, the diffraction efficiency varies according to various properties of structures 224 in an SRG 108. Thus, the processing circuitry may access a table that contains a correspondence between a known diffraction efficiency that results from a structure 224 and a particular refractive index, height, pitch, and/or duty cycle, and determine the SRG layout based on the table.

Operation 916 includes calculating a droplet pattern based on the layout determined in operation 912. For example, the processing circuitry may determine a specific droplet pattern to include x,y coordinates of the resist droplets and spacing on the substrate 208, droplet volume, and/or droplet shape. The droplet pattern may be determined based on the pattern geometry of the SRG 108, the desired diffraction efficiency of the SRG 108, the desired RLT, and/or the fluid dynamics of the resist.

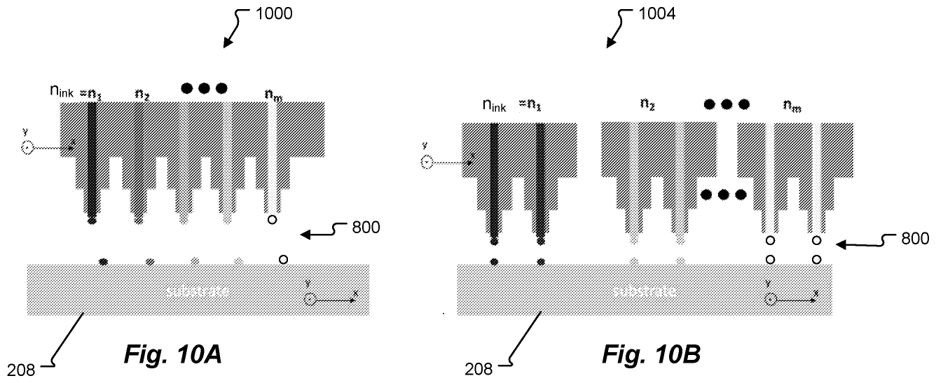

Operation 920 includes dispensing resist according to the desired droplet pattern, which may result in a plurality of droplets 800 on a substrate 208 as in FIGS. 8A and 8B. Operation 920 may be carried out with one or more ink jet devices (see FIGS. 10A and 10B, for example) under control of the processing circuitry. In at least one example embodiment, the volume of the droplets 800 is kept between about 0.5 μL to about l0 μL, or between about 0.5 μL to about 2.0 μL in order to reduce or minimize air bubble trapping while maintaining an acceptable throughput. The viscosity of the droplets 800 is generally below 100 mPas, and in some cases below 30 mPas. In addition, the viscosity of the droplets and the droplet size may be tuned by pre-heating the resist before dispensing. Solvent free or solvent based resist can be used as the droplets 800. The refractive indices of the droplets may be varied by selecting different chemistry (acrylates, siloxane, thiol, etc.) or doping the droplets with metal oxide nanoparticles (ZrO2, TiO2, ZnO, and/or the like) with various concentrations prior to (or after) dispensing. Droplet diameter may be kept between about 10 μm and about 500 μm, or in some cases, between 10 μm to 100 μm.

Operation 924 includes performing a soft bake operation on the dispensed resist. Operation 924 may be performed when using a solvent-based resist that may require the soft bake operation to heat the resist to adjust its viscosity in a manner that is useful for imprinting in operation 920. Using a solvent-based resist may enable SRG structures with higher refractive indices compared to a solvent-free resist. If using a solvent-free resist for the droplets 800, then operation 924 may be skipped.

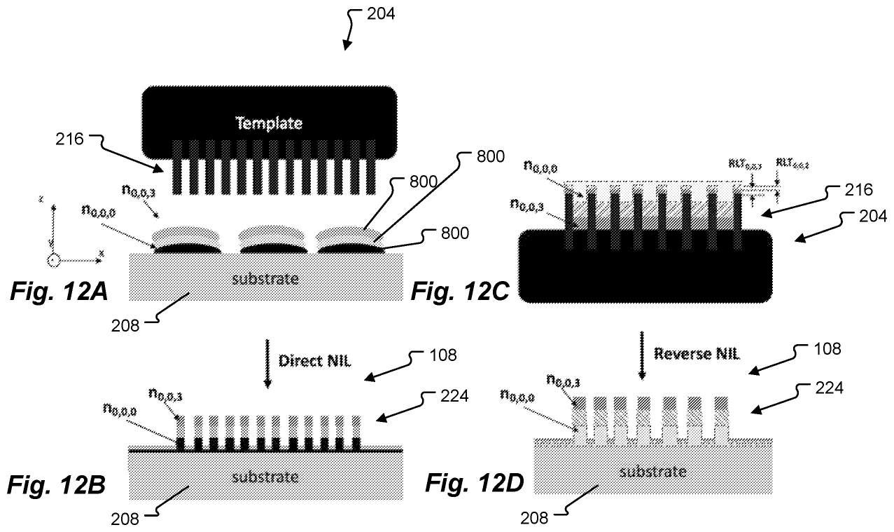

Operation 920 includes imprinting the droplets 800 with a suitable template 204 (e.g., an NIL process). The imprinting may include direct imprinting where the droplets 800 of resist are deposited on the substrate 208 in operation 920 before the template 204 is applied to the substrate 208. Alternatively, the imprinting may include reverse imprinting where the resist droplets are deposited on the template 204 itself. In this case, operation 920 dispenses the droplets on the template 208 and not necessarily the substrate 208. FIG. 12 illustrates examples of direct and reverse NIL imprinting.

Operation 932 includes curing the now imprinted droplets 800. Operation 932 may include performing suitable ultraviolet (UV) curing and/or thermal (heat) curing techniques to hold the structure 224 of the SRG 108 in place. The droplets 800 may be selected to have similar curing energies (e.g., curing time <5 sec) in order to optimize throughput.

Operation 936 includes performing one or more suitable demolding operations to remove the template 204 from the substrate 208 to reveal the SRG 108.

As noted above, the droplets 800 may be deposited with one or more ink jet devices according to suitable ink jet techniques. FIGS. 10A and 10B illustrate example ink jet devices 1000 and 1004 according to at least one example embodiment.

The droplets 800 with variable refractive indices may can be dispensed with a multi-nozzle inkjet printhead system as in FIGS. 10A and 10B. The variation of the refractive index for the droplets 800 may be achieved by using a multi-nozzle printhead system with different refractive index resist formulation as in FIG. 10A or by using a multi-printhead system with one individual refractive index resist formulation per system as in FIG. 10B. In any event, the printheads of both systems and/or the substrate 208 are movable along the x, y and/or z axes. In one embodiment, the printheads move parallel to the substrate 208 while the substrate 208 is kept in a fixed position. In another embodiment, the substrate 208 moves while the printheads are kept fixed. In yet another embodiment, both the substrate 208 and the printheads are moved to dispense the droplets 800.

Here, it should be appreciated that FIG. 10A illustrates a printhead with a number of nozzles that equals the number of resists with different refractive indices. However, example embodiments are not limited thereto, and the printhead in FIG. 10A may include more than one nozzle per type of resist (e.g., two nozzles per resist as in FIG. 10B). Meanwhile, FIG. 10B illustrates that each printhead includes two nozzles for each type of resist n₁ to nₘ, but more or fewer nozzles per printhead may be included if desired.

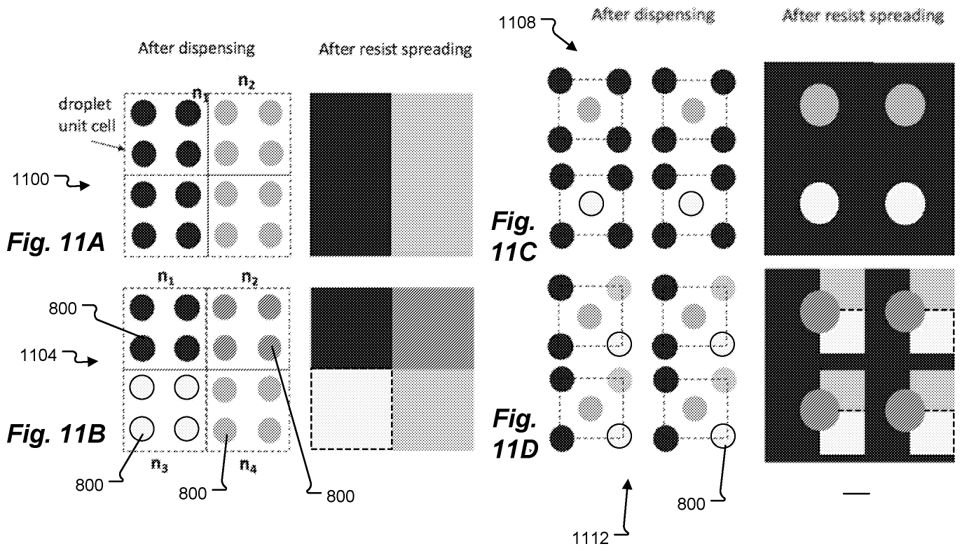

FIGS. 11A to 11D illustrate plan views of various droplet patterns before and after droplet spreading according to at least one example embodiment. That is, the droplets 800 having different indices of refraction may be dispensed in operation 920 according to one of the patterns 1100, 1104, 1108, and 1112 before being spread during imprinting in operation 920.

As may be appreciated from FIGS. 11A to 11D, a variety of refractive index patterns can be created by defining specific droplet unit cells. That is, each droplet pattern 1100, 1104, 1108, and 1112 may include one or more unit cells with droplets in each unit cell. A unit cell may correspond to a unit of area in an SRG 108 formed according to the droplet pattern determined in operation 916. The size of the unit cell may be based on the template 204 used to spread the droplets 800 upon imprinting in operation 920. In at least one embodiment, a unit cell is a minimum unit of area in an SRG 108 formed according to the droplet pattern calculated in operation 916. In at least one example, a unit cell has an area of between about 10 μm and about 500 μm. In some cases, a unit cell has an area of less then 10 μm, for example, about 5 μm. However, example embodiments are not limited thereto and a size and/or shape of a unit cell may vary according to design parameters such as droplet size.

As shown, a unit cell can have one of a variety of geometries and may be periodic or aperiodic. For example, a unit cell may take the form of a Bravais lattice (e.g., square, rectangular, centered rectangular, hexagonal, or oblique lattice). As shown with the greyscale gradations, each droplet in a unit cell may have a specific refractive index in order to spatially vary the refractive index of the SRG 108 to create complex diffractive patterns and functionalities which would be very difficult to achieve by conventional methods. For example, the droplet patterns 1100 and 1104 have a square lattice confirmation with one refractive index per cell while patterns 1108 and 1112 have a square lattice configuration with four refractive indices per cell.

Here, it should be appreciated that FIGS. 11A to 11D are intended to schematically represent the droplets 800 after resist spreading and that the actual structure after resist spreading may take the form of an SRG 108 with structures 224 and vary in shape and size compared to the illustrations in FIGS. 11A to 11D. In one example, some or all of a unit cell may correspond to one or more structures 224 in an SRG 108 after imprinting. Similarly, some or all of a unit cell may correspond to one or more indentations 228 of an SRG 108 after imprinting.

It should be further appreciated that although FIGS. 11A to 11D have been described with reference to droplet patterns that form an SRG 108 with structures 224 and indentations 228, the same or similar concept may be applied to the formation of the entire waveguide 104, including parts of the waveguide 104 that do not include an SRG 108.

As may be appreciated from the above description, ink jet printing and NIL techniques may be used to create an SRG 108 with variable refractive indices in the x and/or y directions. However, the ink jet dispensing process described above may be extended to fabricating photonic structures having variable refractive indices in the vertical direction (z axis) by super-imposing resist dispensing in accordance with the below description.

FIGS. 12A to 12D illustrate methods for forming an SRG 108 with structures 224 having variable refractive indices in a vertical, or z-axis, direction. The refractive index of these photonic structures 224 in three dimensions (n_{x,y,z}) may be controlled and determined by a specific resist drop pattern and numerous combinations are possible. FIGS. 12A and 12B illustrate a direct NIL process where droplets 800 are dispensed on a substrate 208 according to a desired order of index of refraction before being imprinted by a template 204 with structures 216. FIGS. 12C and 12D illustrate a reverse NIL process where the resists with different refractive indices is deposited on the template 204 before the structures 224 are transferred to a substrate 208. For reverse NIL, the residual layer thickness of each resist may be controlled by tuning the thermal annealing or spin-coating conditions when applying the resist to the template 204.

As may be appreciated, FIGS. 12A to 12D illustrate a scenario where three resists n_{0,0,0} to n_{0,0,3} are stacked in a vertical direction for each structure 224. However, example embodiments are not limited thereto and more or fewer resists may be stacked as desired.

In general, the method 900 may be used to form the SRGs 108 in FIGS. 12B and 12D with slight modifications to account for the vertically variable indices of refraction. For example, with reference to FIG. 12A, each droplet 800 of a type of resist may be subjected to a soft baking step to adjust its viscosity before application of another droplet 800 of a different type of resist. The same soft baking concept may be applied to the reverse NIL process in FIG. 12C between applications of resists of different refractive indices.

Although FIGS. 12A-12D depict structures 216 with substantially same heights and structures 224 with substantially same heights and constant duty cycles, it should be appreciated that the heights and duty cycles of structures 216 and 224 may vary as described with reference to FIG. 3A, for example. Similarly, the floor height concepts described with reference to FIGS. 3B to 6 may also apply to the template 204 used in FIGS. 12A to 12D.

As may be appreciated, various figures described herein illustrate representative views to show various interrelationships for aspects of a template 204 and/or for aspects of a waveguide 104 with an SRG 108 (e.g., structure height, horizontal and vertical refractive index adjustment, duty cycle and structure height adjustment, and/or floor height and structure height adjustment). Real-world templates and/or waveguides with SRGs may take any suitable form that meet the desired optical requirements while implementing inventive concepts related to refractive index adjustment, floor height adjustment, and/or duty cycle adjustment.

FIG. 13 illustrates a schematic view of a head mounted display (HMD) 1300 according to at least one example embodiment.

The HMD 1300 may include a wearable frame 10 that supports elements of the HMD 1300, hinges 11 at ends 10A of the frame 10 that enable movement of temple portions 12 that hold the HMD 1300 to the head of an observer 40, ear pieces 13 that removably mount to ears of the observer 40, nose pads 14, wiring 15 that connects to an external processing circuit (not shown) where image processing operations are carried out, for example, on the basis of output from camera 18. The HMD 1300 may further include headphones 16, headphone wirings 17, an image sensor or camera 18 mounted to a face 10B of the frame 10 in a central portion 10C of the frame 10, a member 20 to which image generating devices 111A and 111B are mounted through, for example, a casing 113, and waveguides 104 that rest in front of pupils 41 of the observer 40 when wearing the HMD 1300. As may be appreciated, the image generating devices 111A and 111B may each include an optical system for providing input light to a respective waveguide 104. The optical system for each image generating device 111A and 111B may include one or more light sources, one or more lenses, one or more prisms or mirrors, one or more light modulators, and/or other suitable elements for generating input light for a waveguide 104. Each waveguide 104 take the form of one or more of the waveguides 104 discussed above with reference to FIGS. 1 to 12D and receive the input light shown in FIG. 1 from one of the image generating devices 111A and 111B. For example, one or more of the mechanisms from FIGS. 3A to 12D may be applied to form a waveguide 104.

Here, it should be appreciated that the above described details relate to one non-limiting example of an HMD 1300, and the HMD 1300 may include more or fewer elements than those illustrated and described above.

The embodiments described with reference to FIGS. 1-13 may be combined with one another in any suitable manner. For example, the embodiments described in FIGS. 3A, 3B, 8A to 8D, 11A to 11D, and/or 12A to 12D may be combined with one another as desired.

In view of FIGS. 1-13, at least one example embodiment relates to a waveguide 104 comprising a substrate 208 and a surface relief grating (SRG) 108 comprising at least one waveguide material 212 on the substrate 208. The at least one waveguide material 212 includes a first pattern that alternates between first structures 224 and first indentations 228. The first pattern may a substantially same first pitch over at least a first part of the substrate (e.g., see pattern created in material 212 by structures 216A in FIG. 3A). A residual layer thickness (RLT) of the at least one waveguide material on the substrate over the first part of the substrate is less than a threshold value. In at least one example, the threshold value is about 20 nm. In at least one example embodiment, a change in the RLT over the first part of the substrate is less than about 10 nm/mm. A duty cycle of the first pattern is between 20% and 80% or between 10% and 90%. The first structures 224 may have substantially same heights. The at least one waveguide material 212 includes a second pattern that alternates between second structures 224 and second indentations 228.

The second pattern may have the first pitch over at least a second part of the substrate, and the first structures have different heights than the second structures (e.g., pattern created in material 212 by structures 216B in FIG. 3A). As may be appreciated, the first structures may have greater heights than the second structures, and a duty cycle of the second pattern may be greater than a duty cycle of the first pattern (recalling that the first and second patterns are formed in the waveguide material 212 by, for example, structures 216 of a template 204). In at least one embodiment, a change in the RLT over the first part of the substrate and the second part of the substrate is less than 50 nm/mm. In at least one embodiment, the at least one waveguide material 212 comprises a first waveguide material with a first refractive index and a second waveguide material with a second refractive index different from the first refractive index (see, e.g., FIGS. 8A to 8D). The first structures in the first pattern may comprise structures formed in the first waveguide material and structures formed in the second waveguide material. In at least one embodiment, the at least one waveguide material 212 comprises a first waveguide material with a first refractive index and a second waveguide material with a second refractive index different from the first refractive index, where at least one of the first structures comprises a stacked structure of the first waveguide material and the second waveguide material (see, e.g., FIGS. 12A to 12D). In at least one example, the substrate 208 comprises at least one other waveguide material (i.e., the substrate 208 itself is a waveguide).

In view of FIGS. 1-13, at least one example embodiment is directed to a head mounted device (HMD) 1300 comprising a wearable frame 10 and a waveguide 104 attached to the frame 10. The waveguide 104 may have the substantially the same or similar structures as the waveguide 104 discussed above and where a change in residual layer thickness (RLT) of the at least one waveguide material 212 on the substrate 208 over the first part of the substrate is less than 50 nm/mm. The HMD 1300 may further include an image generating device 111A and/or 111B that generates light input to the waveguide 104.

At least one example embodiment is directed to a template 204 for imprinting optical gratings comprising a base 206 and a plurality of structures 216 protruding from the base and arranged at a substantially same pitch over at least part of the base. At least one of a duty cycle of the plurality of structures 216 and a floor height of the plurality of structures 216 is based on a desired residual layer thickness (RLT) of a material 212 to be imprinted by the template 204. The duty cycle of the plurality of structures is based on a height of at least one structure of the plurality of structures, where the duty cycle of the plurality of structures is defined by a ratio between a width of the plurality of structures and the pitch. In at least one example, the ratio is between 1/5 and 4/5. The ratio may become larger as the height of the at least one structure becomes larger. At least some structures in the plurality of structures 216 have different heights (see, e.g., different groups of structures 21A to 216F in FIGS. 3A and 3B). In at least one example, the at least some structures include groups of structures with substantially same heights (see, e.g., structures 216 in a respective group of structures in FIGS. 3A and 3B). The base 206 may include elevated portions, or floors F, from which the groups of structures protrude. As shown in FIG. 3B, for example, each group of structures 216D to 216F may protrude from a different one of the elevated portions of the base 206, where a height of an elevated portion corresponds to the floor height of one of the groups of structures. In addition, at least some of the elevated portions have different heights. In at least one example, the height of each elevated portion is based on a duty cycle of a respective group of structures, a pitch of the respective group of structures, and a height of the respective group of structures. The height of each elevated portion becomes larger as a height of a respective group of structures becomes smaller.

At least one example embodiment is directed to a template 204B for imprinting optical gratings comprising a base 206 and a plurality of structures 216 protruding from the base and arranged at a substantially same pitch over at least part of the base, where at least some structures in the plurality of structures have different heights, and where a floor height of the plurality of structures is based on a desired residual layer thickness (RLT) of a material to be imprinted by the template.

At least one example embodiment is directed to a template 204A for imprinting optical gratings comprising a base 206 and a plurality of structures 216 protruding from the base and arranged at a substantially same pitch over at least part of the base, where a duty cycle of the plurality of structures is based on a desired residual layer thickness (RLT) of a material to be imprinted by the template. The duty cycle of the plurality of structures is based on a height of at least one structure of the plurality of structures, where the duty cycle of the plurality of structures is defined by a ratio between a width of the plurality of structures and the pitch, and where the ratio becomes larger as the height of the at least one structure becomes larger.

In view of the above, it should be appreciated that at least one example embodiment relates to waveguides with SRGs that have a controlled RLT and methods of forming the same. Controlling the RLT and/or ΔRLT for a waveguide with an SRG may improve KPIs of a display device, such as an HMTD, and the methods described herein provide cost-effective ways for producing such waveguides. In particular, waveguides with SRGs according to example embodiments may provide improved image quality (brightness, resolution, uniformity, etc.) and/or increase the optical performance of the waveguide (eyebox efficiency and uniformity).

While this technology has been described in conjunction with a number of embodiments, it is evident that many alternatives, modifications and variations would be or are apparent to those of ordinary skill in the applicable arts. Accordingly, it is intended to embrace all such alternatives, modifications, equivalents, and variations that are within the spirit and scope of this disclosure.

It should be appreciated that inventive concepts cover any embodiment in combination with any one or more other embodiment, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

It should be appreciated that inventive concepts cover any embodiment in combination with any one or more other embodiments, any one or more of the features disclosed herein, any one or more of the features as substantially disclosed herein, any one or more of the features as substantially disclosed herein in combination with any one or more other features as substantially disclosed herein, any one of the aspects/features/embodiments in combination with any one or more other aspects/features/embodiments, use of any one or more of the embodiments or features as disclosed herein. It is to be appreciated that any feature described herein can be claimed in combination with any other feature(s) as described herein, regardless of whether the features come from the same described embodiment.

Example embodiments may be configured according to the following:
(1) A waveguide, comprising:
   a substrate; and
   a surface relief grating (SRG) comprising at least one waveguide material on the substrate, the at least one waveguide material including a first pattern that alternates between first structures and first indentations, the first pattern having a substantially same first pitch over at least a first part of the substrate, wherein a residual layer thickness (RLT) of the at least one waveguide material on the substrate over the first part of the substrate is less than a threshold value.
(2) The waveguide of (1), wherein the threshold value is about 20 nm.
(3) The waveguide of one or more of (1) to (2), wherein a change in the RLT over the first part of the substrate is less than about 10 nm/mm.
(4) The waveguide of one or more of (1) to (3), wherein a duty cycle of the first pattern is between 20% and 80%.
(5) The waveguide of one or more of (1) to (4), wherein a duty cycle of the first pattern is between 10% and 90%.
(6) The waveguide of one or more of (1) to (5), wherein the first structures have substantially same heights.
(7) The waveguide of one or more of (1) to (6), wherein the at least one waveguide material includes a second pattern that alternates between second structures and second indentations, the second pattern having the first pitch over at least a second part of the substrate, and wherein the first structures have different heights than the second structures.
(8) The waveguide of one or more of (1) to (7), wherein the first structures have greater heights than the second structures, and wherein a duty cycle of the second pattern is greater than a duty cycle of the first pattern.
(9) The waveguide of one or more of (1) to (8), wherein a change in the RLT over the first part of the substrate and the second part of the substrate is less than 50 nm/mm.
(10) The waveguide of one or more of (1) to (9), wherein the at least one waveguide material comprises a first waveguide material with a first refractive index and a second waveguide material with a second refractive index different from the first refractive index, and wherein the first structures in the first pattern comprise structures formed in the first waveguide material and structures formed in the second waveguide material.
(11) The waveguide of one or more of (1) to (10), wherein the at least one waveguide material comprises a first waveguide material with a first refractive index and a second waveguide material with a second refractive index different from the first refractive index, and wherein at least one of the first structures comprises a stacked structure of the first waveguide material and the second waveguide material.
(12) The waveguide of one or more of (1) to (11), wherein the substrate comprises at least one other waveguide material.
(13) A head mounted device (TIMID), comprising:
   a wearable frame;
   a waveguide attached to the frame, the waveguide including:
      a substrate; and
      a surface relief grating (SRG) comprising at least one waveguide material on the substrate, the at least one waveguide material including a first pattern that alternates between first structures and first indentations, the first pattern having a substantially same first pitch over at least a first part of the substrate, wherein a change in residual layer thickness (RLT) of the at least one waveguide material on the substrate over the first part of the substrate is less than 50 nm/mm; and
   an image generating device that generates light input to the waveguide.
(14) The HMD of (13), wherein the at least one waveguide material includes a second pattern that alternates between second structures and second indentations, the second pattern having the first pitch over at least a second part of the substrate, and wherein the first structures have different heights than the second structures.
(15) The HMD of one or more of (13) to (14), wherein the first structures have greater heights than the second structures, and wherein a duty cycle of the second pattern is less a duty cycle of the first pattern.
(16) The HMD of one or more of (13) to (15), wherein a change in the RLT over the first part of the substrate and the second part of the substrate is less than 50 nm/mm.
(17) The HMD of one or more of (13) to (16), wherein the at least one waveguide material comprises a first waveguide material with a first refractive index and a second waveguide material with a second refractive index different from the first refractive index, and wherein the first structures in the first pattern comprise structures formed in the first waveguide material and structures formed in the second waveguide material.
(18) The HMD of one or more of (13) to (17), wherein the at least one waveguide material comprises a first waveguide material with a first refractive index and a second waveguide material with a second refractive index different from the first refractive index, and wherein at least one of the first structures comprises a stacked structure of the first waveguide material and the second waveguide material.
(19) A template for imprinting optical gratings, comprising:
   a base; and
   a plurality of structures protruding from the base and arranged at a substantially same pitch over at least part of the base, wherein at least one of a duty cycle of the plurality of structures and a floor height of the plurality of structures is based on a desired residual layer thickness (RLT) of a material to be imprinted by the template.
(20) The template of (19), wherein the duty cycle of the plurality of structures is based on a height of at least one structure of the plurality of structures, and wherein the duty cycle of the plurality of structures is defined by a ratio between a width of the plurality of structures and the pitch, and wherein the ratio is between 1/5 and 4/5.
(21) The template of one or more of (19) to (20), wherein the duty cycle of the plurality of structures is based on a height of at least one structure of the plurality of structures.
(22) The template of one or more of (19) to (21), wherein the plurality of structures have a substantially same height.
(23) The template of one or more of (19) to (22), wherein the ratio becomes larger as the height of the at least one structure becomes larger.
(24) The template of one or more of (19) to (23), wherein at least some structures in the plurality of structures have different heights.
(25) The template of one or more of (19) to (24), wherein the at least some structures include groups of structures with substantially same heights.
(26) The template of one or more of (19) to (25), wherein the base includes elevated portions from which the groups of structures protrude.
(27) The template of one or more of (19) to (26), wherein each group of structures protrude from a different one of the elevated portions of the base, and wherein a height of an elevated portion corresponds to the floor height of one of the groups of structures.
(28) The template of one or more of (19) to (27), wherein at least some of the elevated portions have different heights.
(29) The template of one or more of (19) to (28), wherein the height of each elevated portion is based on a duty cycle of a respective group of structures, a pitch of the respective group of structures, and a height of the respective group of structures.
(30) The template of one or more of (19) to (29), wherein the height of each elevated portion becomes larger as a height of a respective group of structures becomes smaller.
(31) A template for imprinting optical gratings, comprising:
   a base; and
   a plurality of structures protruding from the base and arranged at a substantially same pitch over at least part of the base, wherein at least some structures in the plurality of structures have different heights, and wherein a floor height of the plurality of structures is based on a desired residual layer thickness (RLT) of a material to be imprinted by the template.
(32) The template of (31), wherein the at least some structures include groups of structures with substantially same heights.
(33) The template of one or more of (31) to (32), wherein the base includes elevated portions from which the groups of structures protrude, wherein each group of structures protrude from a different one of the elevated portions of the base, and wherein a height of an elevated portion corresponds to the floor height of one of the groups of structures.
(34) The template one or more of (31) to (33), wherein the height of each elevated portion is based on a duty cycle of a respective group of structures, a pitch of the respective group of structures, and a height of the respective group of structures.
(35) A template for imprinting optical gratings, comprising:
   a base; and
   a plurality of structures protruding from the base and arranged at a substantially same pitch over at least part of the base, wherein a duty cycle of the plurality of structures is based on a desired residual layer thickness (RLT) of a material to be imprinted by the template.
(36) The template of (35), wherein the duty cycle of the plurality of structures is based on a height of at least one structure of the plurality of structures.
(37) The template of one or more of (35) to (36), wherein the duty cycle of the plurality of structures is defined by a ratio between a width of the plurality of structures and the pitch, and wherein the ratio becomes larger as the height of the at least one structure becomes larger.

Any one or more of the aspects/embodiments as substantially disclosed herein.

Any one or more of the aspects/embodiments as substantially disclosed herein optionally in combination with any one or more other aspects/embodiments as substantially disclosed herein.

One or more means adapted to perform any one or more of the above aspects/embodiments as substantially disclosed herein.

What is claimed is:

1. A waveguide, comprising:
a substrate; and
a surface relief grating (SRG) comprising at least one waveguide material on the substrate, the at least one waveguide material including a first pattern that alternates between first structures and first indentations, the first pattern having a substantially same first pitch over at least a first part of the substrate, wherein a residual layer thickness (RLT) of the at least one waveguide material on the substrate over the first part of the substrate is less than a threshold value.

2. The waveguide of claim 1, wherein the threshold value is about 20 nm.

3. The waveguide of claim 1, wherein a change in the RLT over the first part of the substrate is less than about 10 nm/mm.

4. The waveguide of claim 1, wherein a duty cycle of the first pattern is between 20% and 80%.

5. The waveguide of claim 1, wherein a duty cycle of the first pattern is between 10% and 90%.

6. The waveguide of claim 1, wherein the first structures have substantially same heights.

7. The waveguide of claim 1, wherein the at least one waveguide material includes a second pattern that alternates between second structures and second indentations, the second pattern having the first pitch over at least a second part of the substrate, and wherein the first structures have different heights than the second structures.

8. The waveguide of claim 7, wherein the first structures have greater heights than the second structures, and wherein a duty cycle of the second pattern is greater than a duty cycle of the first pattern.

9. The waveguide of claim 7, wherein a change in the RLT over the first part of the substrate and the second part of the substrate is less than 50 nm/mm.

10. The waveguide of claim 1, wherein the at least one waveguide material comprises a first waveguide material with a first refractive index and a second waveguide material with a second refractive index different from the first refractive index, and wherein the first structures in the first pattern comprise structures formed in the first waveguide material and structures formed in the second waveguide material.

11. The waveguide of claim 1, wherein the at least one waveguide material comprises a first waveguide material with a first refractive index and a second waveguide material with a second refractive index different from the first refractive index, and wherein at least one of the first structures comprises a stacked structure of the first waveguide material and the second waveguide material.

12. The waveguide of claim 1, wherein the substrate comprises at least one other waveguide material.

13. A head mounted device (HMD), comprising:
a wearable frame;
a waveguide attached to the frame, the waveguide including:
a substrate; and
a surface relief grating (SRG) comprising at least one waveguide material on the substrate, the at least one waveguide material including a first pattern that alternates between first structures and first indentations, the first pattern having a substantially same first pitch over at least a first part of the substrate, wherein a change in residual layer thickness (RLT) of the at least one waveguide material on the substrate over the first part of the substrate is less than 50 nm/mm; and
an image generating device that generates light input to the waveguide.

14. The HMD of claim 13, wherein the at least one waveguide material includes a second pattern that alternates between second structures and second indentations, the second pattern having the first pitch over at least a second part of the substrate, and wherein the first structures have different heights than the second structures.

15. The HMD of claim 14, wherein the first structures have greater heights than the second structures, and wherein a duty cycle of the second pattern is greater than a duty cycle of the first pattern.

16. The HMD of claim 15, wherein a change in the RLT over the first part of the substrate and the second part of the substrate is less than 50 nm/mm.

17. The HMD of claim 13, wherein the at least one waveguide material comprises a first waveguide material with a first refractive index and a second waveguide material with a second refractive index different from the first refractive index, and wherein the first structures in the first pattern comprise structures formed in the first waveguide material and structures formed in the second waveguide material.

18. The HMD of claim 13, wherein the at least one waveguide material comprises a first waveguide material with a first refractive index and a second waveguide material with a second refractive index different from the first refractive index, and wherein at least one of the first structures comprises a stacked structure of the first waveguide material and the second waveguide material.

19. A template for imprinting optical gratings, comprising:
a base; and
a plurality of structures protruding from the base and arranged at a substantially same pitch over at least part of the base, wherein at least one of a duty cycle of the plurality of structures and a floor height of the plurality of structures is based on a desired residual layer thickness (RLT) of a material to be imprinted by the template.

20. The template of claim 19, wherein the duty cycle of the plurality of structures is based on a height of at least one structure of the plurality of structures, and wherein the duty cycle of the plurality of structures is defined by a ratio between a width of the plurality of structures and the pitch, and wherein the ratio is between 1/5 and 4/5.
